(19) United States
(12) Patent Application Publication
(10) Pub. No.: US 2016/0372710 A1
(43) Pub. Date: Dec. 22, 2016

(54) FUNCTIONAL LAMINATED FILM, METHOD FOR PRODUCING FUNCTIONAL LAMINATED FILM, AND ORGANIC ELECTROLUMINESCENT DEVICE INCLUDING FUNCTIONAL LAMINATED FILM

(71) Applicant: FUJIFILM Corporation, Tokyo (JP)

(72) Inventors: Eijiro IWASE, Kanagawa (JP); Kana MOROHASHI, Kanagawa (JP); Satoshi KUNIYASU, Kanagawa (JP)

(73) Assignee: FUJIFILM Corporation, Tokyo (JP)

(21) Appl. No.: 15/255,124

(22) Filed: Sep. 1, 2016

Related U.S. Application Data
(63) Continuation of application No. PCT/JP2015/050312, filed on Jan. 8, 2015.

(30) Foreign Application Priority Data
Mar. 19, 2014 (JP) 2014-056286

(51) Int. Cl. H01L 51/52

(52) U.S. Cl. CPC H01L 51/5268; H01L 51/5256; H01L 2251/303; H01L 2251/5369

(57) ABSTRACT

A functional laminated film includes a gas barrier film; and a light-extracting layer provided on the surface of the gas barrier film, in which the gas barrier film includes a base film and a barrier laminate which is provided on the base film and includes an organic layer and an inorganic layer, the inorganic layer and the light-diffusing layer are in direct contact with each other, and the light-diffusing layer is a layer formed from a light-diffusing layer forming material including organic light-diffusing particles and a binder that contains titanium oxide fine particles, a polyfunctional acrylic monomer, and a silane coupling agent.

### CROSS-REFERENCE TO RELATED APPLICATIONS

This application is a Continuation of PCT International Application No. PCT/JP2015/50312, filed on Jan. 8, 2015, which claims priority under 35 U.S.C. §119(a) to Japanese Patent Application No. 2014-056286, filed on Mar. 19, 2014. Each of the above application(s) is hereby expressly incorporated by reference, in its entirety, into the present application.

### BACKGROUND OF THE INVENTION

1. Field of the Invention

The present invention relates to a functional laminated film. More specifically, the present invention relates to a functional laminated film having a light-extracting layer on a gas barrier film and a method for producing the same. Further, the present invention relates to an organic electroluminescent device including a functional laminated film.

2. Description of the Related Art

In the related art, an organic electroluminescent device having a light-extracting layer provided between an organic electroluminescent layer and a substrate thereof has been suggested. The light-extracting layer is a layer provided to increase the extraction efficiency of light emitted from the organic electroluminescent layer, which is decreased due to a difference in refractive index between the organic electroluminescent layer and the substrate, and the structures thereof have been examined in various manners (for example, JP2012-109255A and JP2012-155177A).

Meanwhile, in order to prepare an organic electroluminescent device having flexibility, in the related art, research on using a gas barrier film having a laminated structure of an organic layer and an inorganic layer as a substrate has been made (for example, JP2009-81122A).

### SUMMARY OF THE INVENTION

In an organic electroluminescent device having flexibility, there is a possibility that a problem of each layer, constituting the organic electroluminescent device, peeling off at the time of curvature may occur. The solution to this problem has constantly been an issue in the preparation of an organic electroluminescent device having flexibility.

Moreover, at the time of preparing an organic electroluminescent device, multiple respective layers of a light-extracting layer, a transparent electrode and an organic electroluminescent layer, and a reflective electrode are laminated on a substrate. Here, in a case of using a gas barrier film as a substrate, it is preferable that a light-extracting layer is provided on the surface of an inorganic layer in the gas barrier film. However, based on research conducted by the present inventors, in a case where a gas barrier film having an inorganic layer on the outermost surface thereof is used as a substrate, the inorganic layer on the outermost surface is occasionally damaged, for example, due to contact of the inorganic layer with a pass roll in a roll-to-roll production process. For this reason, when a gas barrier film is used as a substrate of an organic electroluminescent device, it is expected that the inorganic layer will be easily damaged and the yield thereof will decrease in some cases during a conveying process for forming multiple layers as described above.

In view of the above-described problems, an object of the present invention is to provide a functional laminated film which has light-extracting performance, barrier properties, and flexibility and in which a problem of peeling is unlikely to occur at the time of curvature, processing such as cutting or the like during the production process, or conveyance. Further, another object of the present invention is to provide a functional laminated film which can be used as a member of an organic electroluminescent device and has flexibility and in which a configuration layer is unlikely to be damaged even when an additional member such as a protective film is not provided. Furthermore, another object of the present invention is to provide a method for producing a functional laminated film and an organic electroluminescent device including a functional laminated film.

In order to solve the above-described problems, the present inventors conducted intensive research and found that the problem of peeling can be reduced and damage to an inorganic layer in a gas barrier film in contact with a light-diffusing layer can be suppressed by adding a silane coupling agent to a light-diffusing layer forming material in a light-extracting layer, thereby completing the present invention based on this finding.

In other words, the present invention provides the following [1] to [16].

[1] A functional laminated film comprising: a gas barrier film; and a light-extracting layer provided on the surface of the gas barrier film, in which the gas barrier film includes a base film and a barrier laminate provided on the base film, the barrier laminate includes an organic layer and an inorganic layer, the light-extracting layer includes a light-diffusing layer and a planarizing layer, the inorganic layer and the light-diffusing layer are in direct contact with each other, the light-diffusing layer is a layer formed of a light-diffusing layer forming material including light-diffusing particles and a binder, the light-diffusing particles are organic particles, and the binder contains titanium oxide fine particles, a polyfunctional acrylic monomer, and a silane coupling agent.

[2] The functional laminated film according to [1], in which the silane coupling agent has a (meth)acryloyl group.

[3] The functional laminated film according to [1] or [2], in which the polyfunctional acrylic monomer has a fluorene skeleton.

[4] The functional laminated film according to any one of [1] to [3], in which the binder includes a fluorine-based surfactant.

[5] The functional laminated film according to any one of [1] to [4], in which the barrier laminate includes an organic layer, an inorganic layer, an organic layer, and an inorganic layer in this order from the base film side.

[6] The functional laminated film according to any one of [1] to [5], in which the inorganic layer in contact with the light-diffusing layer includes at least one of silicon nitride, silicon oxide, or silicon oxynitride.

[7] The functional laminated film according to any one of [1] to [6], in which the film thickness of the light-diffusing layer is in a range of 0.5 μm to 15 μm.

[8] The functional laminated film according to any one of [1] to [7], in which the film thickness of the light-extracting layer is in a range of 1 μm to 20 μm.

[9] The functional laminated film according to any one of [1] to [8], in which the total film thickness of the barrier laminate and the light-extracting layer is in a range of 1.5 μm to 30 μm.

[10] The functional laminated film according to any one of [1] to [9], in which a mixed layer between the light-diffusing layer and the planarizing layer, which has a film thickness of 5 nm or greater, is interposed between the light-diffusing layer and the planarizing layer, and a Si—O—Si bond is formed at the interface between the light-diffusing layer and the inorganic layer in contact with the light-diffusing layer.

[11] A method for producing the functional laminated film according to any one of [1] to [10], comprising: (1) coating the surface of an inorganic layer which is the surface of a gas barrier film with the light-diffusing layer forming material; (2) irradiating a laminate formed of the gas barrier film and the light-diffusing layer forming material coated film, which is obtained after the coating, with light; (3) coating the surface of the light-diffusing layer in a laminate formed of the gas barrier film and the light-diffusing layer, which is obtained after the irradiating of the laminate with light, with a planarizing layer forming material that contains titanium oxide fine particles and a polyfunctional acrylic monomer; and (4) irradiating a laminate formed of the gas barrier film, the light-diffusing layer, and the planarizing layer forming material coated film, which is obtained after the coating, with light, in which the above-described (1) to (4) are continuously performed using a roll-to-roll system that includes winding or rewinding the gas barrier film or any one of the laminates around a roll.

[12] The production method according to [11], further comprising: drying the light-diffusing layer forming material coated film with hot air; and drying the planarizing layer forming material coated film with hot air.

[13] The production method according to [11] or [12], further comprising: conveying the gas barrier film wound around the roll only by holding the end portion thereof using a stepped roll, which is not in contact with the surface of the gas barrier film, before the coating (1), in which the coating (1) is performed using a die coater or a slit coater which is not in contact with the surface of the gas barrier film.

[14] The production method according to any one of [11] to [13], further comprising: heating one or more laminates selected from the group consisting of the laminate formed of the gas barrier film and the light-diffusing layer forming material coated film and the laminate formed of the gas barrier film, the light-diffusing layer, and the planarizing layer forming material coated film, with hot air or using a heating roller.

[15] The production method according to any one of [11] to [14], in which one or more processes of irradiation with light selected from the group consisting of the irradiating (2) of the laminate with light and the irradiating (4) of the laminate with light are performed while heating the respective laminates from the gas barrier film side at 30° C. or higher and less than 100° C.

[16] An organic electroluminescent device comprising a transparent electrode, an organic electroluminescent layer, and a reflective electrode which are provided on the surface of the functional laminated film according to any one of [1] to [10] on the light-extracting layer side in this order.

[17] A functional laminated film comprising: a base film; an inorganic layer; and a light-diffusing layer in direct contact with the inorganic layer, in this order, in which the light-diffusing layer contains organic particles, titanium oxide fine particles, an acrylic polymer, and a silane coupling agent.

The present invention provides a functional laminated film which has light-extracting performance, barrier properties, and flexibility and in which a problem of peeling is unlikely to occur at the time of curvature, processing such as cutting or the like during the production process, or conveyance; and a method for forming a functional laminated film. Further, the present invention provides an organic electroluminescent device including a functional laminated film.

In the functional laminated film of the present invention, since adhesion of the gas barrier film serving as a substrate to the light-extracting layer is high, deterioration of barrier properties due to delamination is suppressed while the flexibility thereof is maintained and a possibility that light-diffusing particles or titanium oxide fine particles in the light-diffusing layer will cause dust due to delamination is reduced. Moreover, according to the method for producing a functional laminated film of the present invention, the inorganic layer in the gas barrier film is unlikely to be destructed.

### BRIEF DESCRIPTION OF THE DRAWING

FIG. 1 is a sectional view schematically illustrating an example of a functional laminated film of the present invention.

### DESCRIPTION OF THE PREFERRED EMBODIMENTS

Hereinafter, the contents of the present invention will be described in detail. In addition, the numerical ranges shown using “to” in the present specification indicate ranges including the numerical values shown before and after “to” as the lower limits and the upper limits. In the present specification, the term “(meth)acrylate” indicates “any one or both of acrylate and methacrylate.” The same applies to a “(meth)acryloyl group” or the like.

<Functional Laminated Film>

In the present specification, a functional laminated film indicates a film having barrier properties, flexibility, and additional optical functions. Examples of the optical functions include a function of efficiently extracting light emitted from a light emitting element or the like provided on one surface side of the film toward another surface, and a function of diffusing (scattering) light emitted from a light emitting element or the like provided on one surface of the film toward another surface. The functional laminated film can be used as a film substrate for an organic electroluminescent device.

The functional laminated film includes a gas barrier film and a light-extracting layer and has a laminated structure of the gas barrier film and the light-extracting layer. The gas barrier film is in direct contact with the light-extracting layer, and one inorganic layer in the gas barrier film and a light-diffusing layer in the light-extracting layer are in direct contact with each other. In the functional laminated film, both outer sides of the laminate formed of the gas barrier film and the light-extracting layer may or may not include other layers, but it is preferable that the outer sides thereof do not include other layers. A protective layer and the like may be exemplified as other layers on the outer sides thereof.

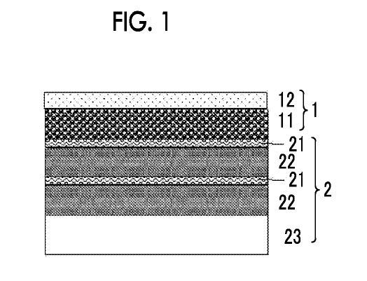

FIG. 1 is a sectional view schematically illustrating an example of the functional laminated film. In the example illustrated in FIG. 1, the gas barrier film has a structure in which an organic layer, an inorganic layer, an organic layer, and an inorganic layer are laminated from a base film side in this order, and the inorganic layer provided on a side far from the base film side is in direct contact with the light-diffusing layer in the light-extracting layer.

The film thickness of the functional laminated film is preferably in a range of 20 μm to 200 μm and more preferably in a range of 30 μm to 150 μm.

Hereinafter, each layer included in the functional laminated film will be described.

<Light-Extracting Layer>

The light-extracting layer may have a function of efficiently extracting or diffusing light emitted from a light emitting element or the like provided on one surface side of the layer toward another surface. For example, in a case where the functional laminated film is used as a film substrate for an organic electroluminescent device, light emitted from an organic electroluminescent layer may be efficiently extracted and diffused to the gas barrier film that is another surface side with a configuration in which the organic electroluminescent layer is formed on one surface side of the light-extracting layer.

The film thickness of the light-extracting layer is preferably in a range of 1 μm to 20 μm and more preferably in a range of 3 μm to 15 μm.

The light-extracting layer includes a light-diffusing layer and a planarizing layer. The light-extracting layer may include other layers other than the light-diffusing layer and the planarizing layer, but it is preferable that the light-extracting layer is formed of the light-diffusing layer and the planarizing layer. In the functional laminated film, the light-diffusing layer is disposed on the gas barrier film side and is in contact with the inorganic layer in the gas barrier film.

<Light-Diffusing Layer>

A light-diffusing layer has a function of efficiently extracting or diffusing light emitted from a light emitting element or the like provided on one surface side of the layer toward another surface. Specifically, the refractive index thereof may be adjusted to be greater than that of a glass substrate (n (refractive index)=approximately 1.5) or a polymer layer (n=approximately 1.6) formed through polymerization of (meth)acrylate.

The light-diffusing layer is formed from a light-diffusing layer forming material containing light-diffusing particles and a binder. The light-diffusing layer forming material may be formed as a dispersion liquid obtained by dispersing light-diffusing particles in a binder described below. The light-diffusing layer forming material can be prepared by stirring a binder and light-diffusing particles so that the binder and the particles are mixed and adding respective components of the binder and the light-diffusing particles to a solvent to be mixed to each other.

<Binder>

A binder is a composition containing titanium oxide fine particles, a polyfunctional acrylic monomer, and a silane coupling agent. The binder may contain other components as needed.

<Titanium Oxide Fine Particles>

The refractive index of the light-diffusing layer can be increased by adding titanium oxide fine particles. The titanium oxide fine particles are not particularly limited, but it is preferable to use titanium oxide fine particles subjected to a photocatalyst inactive treatment. Examples of the titanium oxide fine particles subjected to a photocatalyst inactive treatment include (1) titanium oxide fine particles formed by covering the surface of the titanium oxide fine particles with at least one of alumina, silica, or zirconia, and (2) titanium oxide fine particles formed by covering the surface, covered with the titanium oxide fine particles covered in the above-described (1), with a resin. Examples of the resin include polymethyl methacrylate (PMMA).

It can be confirmed that the titanium oxide fine particles subjected to a photocatalyst inactive treatment do not have photocatalyst activity according to a methylene blue method.

Titanium oxide fine particles in the titanium oxide fine particles subjected to a photocatalyst inactive treatment are not particularly limited and can be suitably selected according to the purpose. As a crystal structure thereof, a crystal structure of rutile, a mixed crystal structure of rutile and anatase, or a crystal structure having anatase as a main component is preferable and a crystal structure having rutile as a main component is particularly preferable.

The titanium oxide fine particles may be composited by adding metal oxides other than titanium oxide thereto.

As the metal oxides which are capable of compositing the titanium oxide fine particles, at least one metal oxide selected from Sn, Zr, Si, Zn, and Al is preferable. The amount of the metal oxide to be added is preferably in a range of 1% by mole to 40% by mole, more preferably in a range of 2% by mole to 35% by mole, and still more preferably in a range of 3% by mole to 30% by mole with respect to titanium.

The primary average particle diameter of the titanium oxide fine particles is preferably in a range of 1 nm to 30 nm, more preferably in a range of 1 nm to 25 nm, and still more preferably in a range of 1 nm to 20 nm. When the primary average particle diameter thereof exceeds 30 nm, a dispersion liquid is clouded and precipitation occurs in some cases. When the primary average particle diameter thereof is less than 1 nm, the crystal structure becomes unclear and close to an amorphous shape, and a change such as gelation occurs with time.

The primary average particle diameter can be measured through calculation of a half width of a diffraction pattern measured using an X-ray diffractometer or through statistic calculation of diameters of captured images using an electron microscope (TEM). In the present specification, the primary average particle diameter is based on the value measured through statistic calculation of diameters of captured images using an electron microscope (TEM).

The shape of the titanium oxide fine particles is not particularly limited and can be suitably selected according to the purpose thereof, and preferred examples thereof include a rice grain shape, a spherical shape, a cubic shape, a spindle shape, and an amorphous shape. The titanium oxide fine particles may be used alone or in combination of two or more kinds thereof.

In addition, the average secondary particle diameter of the titanium oxide fine particles is preferably 100 nm or less, more preferably 80 nm or less, and still more preferably 70 nm or less.

While the primary particle diameter is defined as a particle diameter in a state in which fine particles are ideally dispersed, the secondary particle diameter is defined as the size of an aggregate when the primary particles thereof are aggregated in a certain state (in an environment). In a dispersion liquid containing typical fine particles, the particles are occasionally aggregated in a state of having a certain size. Examples of the method of measuring the average secondary particle diameter include a dynamic light scattering method, a laser diffraction method, and an image imaging method. The value of the average secondary particle diameter defined in the present specification is based on the dynamic light scattering method.

As a method of controlling the average secondary particle diameter, addition of a dispersant may be exemplified. The dispersion state is controlled using the type and the addition amount of the dispersant and thus the average secondary particle diameter is adjusted.

The dispersant is not particularly limited, and examples thereof include an amine-based dispersant, a polycarboxylic acid alkyl ester-based dispersant, and a polyether-based dispersant. Commercially available products in which particles are dispersed to have a desired average secondary particle diameter may be used.

The refractive index of the titanium oxide fine particles is preferably in a range of 2.2 to 3.0, more preferably in a range of 2.2 to 2.8, and still more preferably in a range of 2.2 to 2.6. It is preferable that the refractive index thereof is 2.2 or greater from the viewpoint that the refractive index of the light-diffusing layer can be effectively increased. Further, it is preferable that the refractive index is 3.0 or less from the viewpoint that inconvenience, for example, coloration of the titanium oxide fine particles does not occur.

Here, although it is difficult to measure the refractive index of fine particles having a high refractive index (1.8 or greater), such as titanium oxide fine particles, and having an average primary particle diameter of approximately 1 nm to 100 nm, the refractive index thereof can be measured in the following manner. Titanium oxide fine particles are doped in a resin material whose refractive index is known and a Si substrate or a quartz substrate is coated with the resin material in which the titanium oxide fine particles are dispersed to form a coated film. The refractive index of the coated film is measured using an ellipsometer, and the refractive index of the titanium oxide fine particles is obtained from the volume fraction of the titanium oxide fine particles and the resin material constituting the coated film.

The content of the titanium oxide fine particles calculated from the following equation is in a range of 10% by volume to 30% by volume, more preferably in a range of 10% by volume to 25% by volume, and still more preferably in a range of 10% by volume to 20% by volume with respect to the volume (excluding a solvent) of the binder.

Equation: Content (% by volume) of titanium oxide fine particles=(mass of titanium oxide fine particles/4(specific weight))/{(mass of titanium oxide fine particles/4(specific weight))+(mass of polyfunctional acrylic monomer/specific weight of polyfunctional acrylic monomer)}

<Polyfunctional Acrylic Monomer>

In the present specification, the “polyfunctional acrylic monomer” indicates a monomer having two or more (meth)acryloyl groups. Specifically, compounds described in paragraphs [0024] to [0036] of JP2013-43382A and paragraphs [0036] to [0048] of JP2013-43384A can be used as the polyfunctional acrylic monomer. It is preferable that the polyfunctional acrylic monomer has a fluorene skeleton.

As the polyfunctional acrylic monomer having a fluorene skeleton, compounds represented by Formula (2) described in WO2013-047524A may be exemplified. Specific examples are described below. In the examples described below, a compound represented by Formula (I) is particularly preferable.

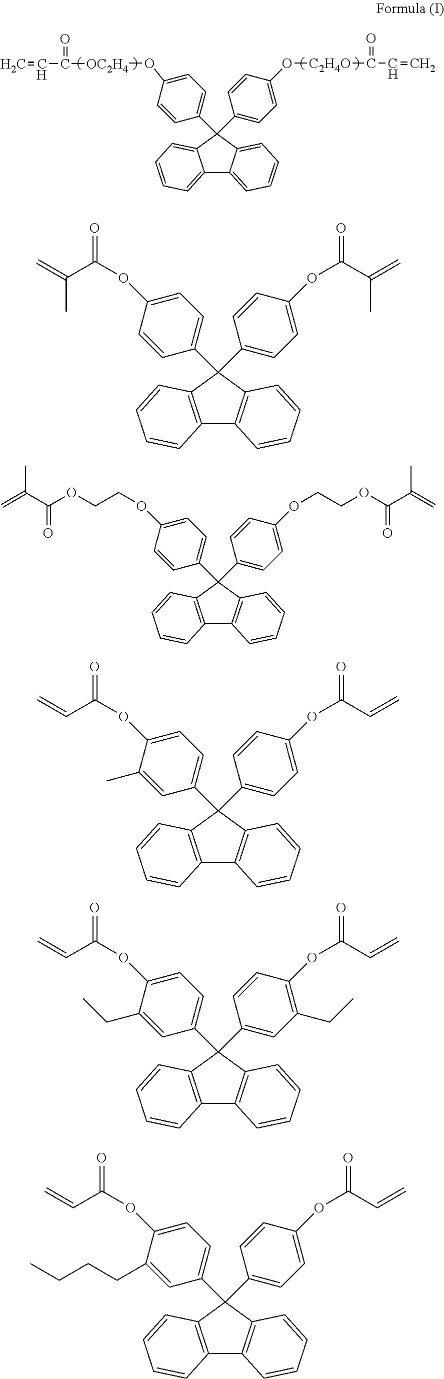

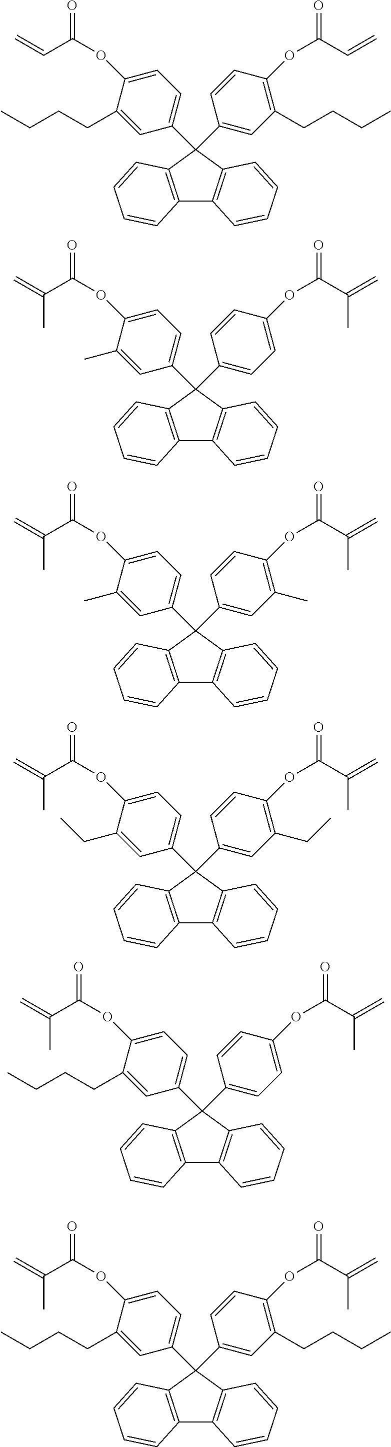

As the polyfunctional acrylic monomer, an acrylic monomer having a volume shrinkage rate of 10% or less is preferable and an acrylic monomer having a volume shrinkage rate of 5% or less is more preferable.

The volume shrinkage rate indicates a difference in volume between a monomer state before ultraviolet curing and a polymer state after curing (“Poor UV-hardening/Obstructionistic factor and Measures” by Technical Information Institute Co., Ltd., first edition published on Dec. 11, 2003, see Section 3 of Chapter 1). The volume shrinkage rate can be obtained through thickness measurement before and after curing or measurement according to a method of measuring the amount of curls when formed on a plastic film. Further, the volume shrinkage rate can be also measured using a typical measuring device (cured resin shrinkage stress measuring device, manufactured by Matsuo Sangyo Co., Ltd.). The volume shrinkage rate can be adjusted by preparing the molecular weight of acrylic monomers or functional groups.

The proportion of the polyfunctional acrylic monomer in the solid content (residues after volatile matters are volatilized) of a binder is preferably in a range of 5% by mass to 50% by mass and more preferably in a range of 10% by mass to 30% by mass.

The binder may include, as an additive, a combination of a thermoplastic resin, a reactive curable resin, and a curing agent, other polyfunctional monomers, or a polyfunctional oligomer described in paragraphs [0020] to [0045] of JP2012-155177A in addition to the polyfunctional acrylic monomer.

<Silane Coupling Agent>

A binder includes a silane coupling agent. As a result of the research conducted by the present inventors, it is understood that an inorganic layer is firmly adhered to a light-diffusing layer and a function of protecting the inorganic layer is provided for the light-diffusing layer by adding a silane coupling agent to the light-diffusing layer forming material provided so as to be in contact with the inorganic layer of the gas barrier film. Particularly, as described below, the inorganic layer is firmly adhered to the light-diffusing layer by coating the surface of the inorganic layer with the light-diffusing layer forming material, heating, irradiating the surface with ultraviolet rays, and forming the light-diffusing layer.

Examples of the silane coupling agent include a compound having a structure in which a hydrolyzable reactive group, for example, an alkyloxy group such as a methoxy group or an ethoxy group or an acetoxy group and a substituent having one or more reactive groups selected from an epoxy group, a vinyl group, an amino group, a halogen group, a mercapto group, and a (meth)acryloyl group are bonded to the same silicon atom; and a compound having a partial structure in which two silicon atoms are bonded to each other through oxygen or —NH— and has a structure in which the above-described hydrolyzable reactive groups and a substituent having the above-described reactive groups are bonded to any one of these silicon atoms. It is particularly preferable that the silane coupling agent includes a (meth)acryloyl group. Specific examples of the silane coupling agent include a silane coupling agent represented by formula (1) described in WO2013/146069A and a silane coupling agent represented by Formula (1) described in WO2013/027786A.

Preferred examples of the silane coupling agent include a silane coupling agent represented by the following Formula (1).

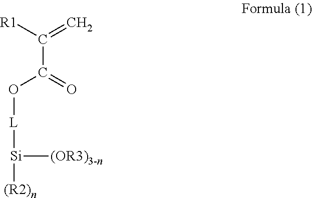

In the formula, R1 represents a hydrogen atom or a methyl group, R2 represents a halogen atom or an alkyl group, R3 represents a hydrogen atom or an alkyl group, L represents a divalent linking group, and n represents an integer of 0 to 2.

Examples of the halogen atom include a chlorine atom, a bromine atom, a fluorine atom, and an iodine atom.

The number of carbon atoms of the alkyl group or the alkyl group included in a substituent among substituents having an alkyl group described below is preferably in a range of 1 to 12, more preferably in a range of 1 to 9, and still more preferably in a range of 1 to 6. Specific examples of the alkyl group include a methyl group, an ethyl group, a propyl group, a butyl group, a pentyl group, and a hexyl group. The alkyl group may be linear, branched, or cyclic, but it is preferable that the alkyl group is linear.

As a divalent linking group, a linking group having 1 to 20 carbon atoms is preferable. The number of carbon atoms of the linking group is preferably in a range of 1 to 12 and more preferably in a range of 1 to 6. Examples of the divalent linking group include an alkylene group (such as an ethylene group, a 1,2-propylene group, a 2,2-propylene group (also referred to as a 2,2-propylidene group or a 1,1-dimethylmethylene group), a 1,3-propylene group, a 2,2-dimethyl-1,3-propylene group, a 2-butyl-2-ethyl-1,3-propylene group, a 1,6-hexylene group, a 1,9-nonylene group, a 1,12-dodecylene group, or a 1,16-hexadecylene group), an arylene group (such as a phenylene group or a naphthylene group), an ether group, an imino group, a carbonyl group, a sulfonyl group, divalent residues (such as a polyethyleneoxyethylene group, a polypropyleneoxypropylene group, and a 2,2-propylenephenylene group) in which a plurality of these divalent groups are serially bonded to each other. These groups may include a substituent. In addition, two or more of these groups may form a linking group in which a plurality of these groups are serially bonded to each other. Among these, an alkylene group, an arylene group, and a divalent group in which a plurality of these groups are serially bonded to each other are preferable, and an unsubstituted alkylene group, an unsubstituted arylene group, and a divalent group in which a plurality of these groups are serially bonded to each other are more preferable. Examples of the substituent include an alkyl group, an alkoxy group, an aryl group, and an aryloxy group.

Hereinafter, specific examples of the silane coupling agent will be described, but the present invention is not limited thereto.

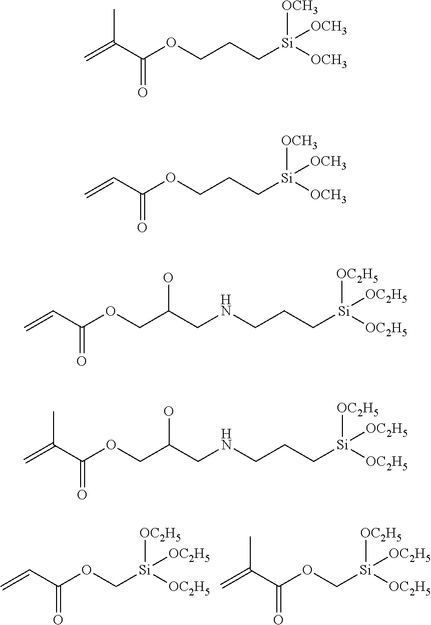 [SMILES: C=C(C)C(=O)OCCC[Si](OC)(OC)OC ; C=CC(=O)OCCC[Si](OC)(OC)OC ; C=CC(=O)OCC(O)CNCCC[Si](OCC)(OCC)OCC ; C=C(C)C(=O)OCC(O)CNCCC[Si](OCC)(OCC)OCC ; C=CC(=O)OC[Si](OCC)(OCC)OCC ; C=C(C)C(=O)OC[Si](OCC)(OCC)OCC]

The proportion of the silane coupling agent in the solid content (residues after volatile matters are volatilized) of the binder is preferably in a range of 1% by mass to 20% by mass and more preferably in a range of 2% by mass to 10% by mass. The binder may include two or more kinds of silane coupling agents. In this case, the total amount thereof may be set to be in the above-described range.

<Polymerization Initiator>

The binder may contain a polymerization initiator.

Examples of the polymerization initiator include photopolymerization initiators described in paragraphs [0046] to [0058] of JP2012-155177A. Specific examples thereof include commercially available IRGACURE series (such as IRGACURE 651, IRGACURE 754, IRGACURE 184, IRGACURE 2959, IRGACURE 907, IRGACURE 369, IRGACURE 379, and IRGACURE 819) (manufactured by Ciba Specialty Chemicals Inc.), DAROCURE series (such as DAROCURE TPO and DAROCURE 1173), QUANTACURE PDO, and EZACURE series (such as EZACURE TZM, EZACURE TZT, and EZACURE KTO46) (manufactured by LAMBERTI S.p.A.). In a case of using a polymerization initiator, the content thereof is preferably 0.1% by mole or greater and more preferably 0.5% by mole to 5% by mole of the total amount of the compound related to the polymerization. With such a composition, it is possible to suitably control the polymerization reaction via an active component generating reaction.

<Fluorine-Based Surfactant>

The binder may contain a fluorine-based surfactant.

Examples of the fluorine-based surfactant include fluorine-based surfactants described in JP2002-255921A, JP2003-114504A, JP2003-140288A, JP2003-149759A, JP2003-195454A, and JP2004-240187A. The surfactant is not particularly limited, and may be anionic, cationic, nonionic, or amphoteric (betaine).

Specific examples of the compound include anionic fluorine-based surfactants of FS-1 to FS-29 described in JP2002-255921A, cationic and amphoteric fluorine-based surfactants of FS-1 to FS-71 described in JP2003-114504A, anionic fluorine-based surfactants of FS-1 to FS-38 described in JP2003-140288A, cationic fluorine-based surfactants of FS-1 to FS-39 described in JP2003-149759A, and anionic, cationic, and nonionic fluorine-based surfactants of FS-1 to FS-32 described in JP2003-195454A.

The content of the fluorine-based surfactant may be 0.01% by mass or greater with respect to the total mass of the solid content (mass obtained after the solvent is removed) of the light-diffusing layer fanning material.

<Solvent>

The binder may be formed by dissolving the above-described respective components in a solvent. The light-diffusing layer fanning material may be prepared as a dispersion liquid obtained by mixing the above-described respective components and light-diffusing particles into a solvent and dispersing the light-diffusing particles in the binder. The solvent is not particularly limited and can be suitably selected according to the purpose thereof, but an organic solvent having a solubility parameter (SP) of 14 (cal/cm³)^{1/2} or less is preferable. Further, 1 (cal/cm³)^{1/2} corresponds to approximately 2.05 (MPa)^{1/2}.

Examples of the solvent include alcohols, ketones, esters, amides, ethers, ether esters, aliphatic hydrocarbons, and halogenated hydrocarbons. Specific examples thereof include alcohols (such as methanol, ethanol, propanol, butanol, benzyl alcohol, ethylene glycol, propylene glycol, and ethylene glycol monoacetate), ketones (such as methyl ethyl ketone, methyl isobutyl ketone, cyclohexanone, and methyl cyclohexanone), esters (such as methyl acetate, ethyl acetate, propyl acetate, butyl acetate, ethyl formate, propyl formate, butyl formate, and ethyl lactate), aliphatic hydrocarbons (such as hexane and cyclohexane), halogenated hydrocarbons (such as methyl chloroform), aromatic hydrocarbons (such as benzene, toluene, xylene, and ethylbenzene), amides (such as dimethylformamide, dimethylacetamide, and n-methylpyrrolidone), ethers (such as dioxane, tetrahydrofuran, ethylene glycol dimethyl ether, and propylene glycol dimethyl ether), and ether alcohols (such as 1-methoxy-2-propanol, ethyl cellosolve, and methyl carbinol). These may be used alone or in combination of two or more kinds thereof. Among these, aromatic hydrocarbon and ketones are preferable, toluene, xylene, methyl ethyl ketone, methyl isobutyl ketone, and cyclohexanone are more preferable, and toluene and xylene are particularly preferable.

<Light-Diffusing Particles>

The light-diffusing particles are not particularly limited as long as the particles are capable of diffusing light and can be suitably selected according to the purpose thereof. In addition, organic particles may be used as the light-diffusing particles. Two or more kinds of light-diffusing particles may be used.

Examples of the organic particles include polymethyl methacrylate particles, cross-linked polymethyl methacrylate particles, acryl-styrene copolymer particles, melamine particles, polycarbonate particles, polystyrene particles, cross-linked polystyrene particles, polyvinyl chloride particles, and benzoguanamine-melamine formaldehyde particles.

Among these, from the viewpoints of solvent resistance and dispersibility in a binder, resin particles in a cross-linked state is preferable and cross-linked polymethyl methacrylate particles are particularly preferable as the light-diffusing particles.

It can be confirmed whether the light-diffusing particles is resin particles in a cross-linked state or not by dispersing the light-diffusing particles in a solvent such as toluen and then observing resistance to dissolution of the resin particles.

The refractive index of the light-diffusing particles is not particularly limited and can be suitably selected according to the purpose thereof, but is preferably in a range of 1.0 to 3.0, more preferably in a range of 1.2 to 1.6, and still more preferably in a range of 1.3 to 1.5. When the refractive index thereof is less than 1.0 or greater than 3.0, since light diffusion (scattering) becomes extremely strong, the light extraction efficiency may decrease.

The refractive index of the light-diffusing particles can be measured according to a shrivski method using a precision spectrometer (GMR-1DA, manufactured by Shimadzu Corporation) after the refractive index of a refractive liquid is measured using, for example, an automatic refractive index measuring device (KPR-2000, manufactured by Shimadzu Corporation).

A difference |A−B| (absolute value) in refractive index between a refractive index A of the binder and a refractive index B of light-diffusing particles is preferably in a range of 0.2 to 1.0, more preferably in a range of 0.2 to 0.5, and still more preferably in a range of 0.2 to 0.4.

The average particle diameter of the light-diffusing particles is preferably in a range of 0.5 μm to 10 μm, more preferably in a range of 0.5 μm to 6 μm, and still more preferably in a range of 1 μm to 3 μm. When the average particle diameter of the light-diffusing particles exceeds 10 μm, most of the light is forward-scattered and an ability of converting the angle of light using the light-diffusing particles is degraded. Meanwhile, when the average particle diameter of the light-diffusing particles is less than 0.5 μm, the particle diameter is smaller than the wavelength of visible light, Mie scattering is changed to be in a region of Rayleigh scattering, and wavelength dependence of scattering efficiency of the light-diffusing particles is increased, so that the chromaticity of an organic electroluminescent device is greatly changed, backscattering becomes stronger, or the light extraction efficiency is degraded.

The average particle diameter of the light-diffusing particles can be measured by means of using a device according to a dynamic light scattering method, such as NANOTRAC UPA-EX150 (manufactured by NIKKISO CO., LTD.), or performing image processing of electron micrography.

The proportion of the light-diffusing particles in the solid content of the binder (residues after volatile matters are volatilized) is preferably in a range of 20% by mass to 50% by mass and more preferably in a range of 25% by mass to 40% by mass.

<Method of Forming Light-Diffusing Layer and Planarizing Layer>

The light-diffusing layer can be formed by coating the surface of the gas barrier film with the light-diffusing layer forming material and curing the coated film. If necessary, the film may be dried after curing and may be heated before, after, or at the time of curing. Moreover, as described below, the planarizing layer may be formed in the same manner as the method of forming the light-diffusing layer except that the layer is not formed on the surface of the gas barrier film, but formed on the surface of the light-diffusing layer.

The surface of the gas barrier film coated with the light-diffusing layer forming material may be formed into an inorganic layer. It is preferable that a Si—O—Si bond is formed between the light-diffusing layer and the inorganic layer. The Si—O—Si bond can be confirmed using FT-IR or the like. Specifically, the presence of a peak of Si—O—Si at approximately 1050 cm⁻¹ may be confirmed.

It is preferable that the processes of coating, drying, and curing are continuously performed using a roll-to-roll (RtoR) system. That is, it is preferable that the processes are continuously performed while the gas barrier film or the laminate is wound around a roll or rewound into (unwound from) the roll. Further, it is preferable that the light-diffusing layer and the planarizing layer, formed in the same manner as that of the light-diffusing layer, are formed by continuously performing processes. The continuous processes can be referred to the description of JP2013-031794A.

In the above-described processes, it is preferable that the final reaching temperature of the coated film is higher than the boiling point of the solvent of the light-diffusing forming material (binder), the solvent of the planarizing layer foaming material, a by-product of a silane coupling agent, or the azeotropic point of these solvents. The heating process can be performed by heating the whole gas barrier film which becomes a substrate according to a method of using drying air or hot air or a method of using a heating roller.

It is preferable to use a stepped roll, which is not in contact with the surface of the gas barrier film, as a pass roll used at the time of conveyance in the roll-to-roll system for coating the surface of the inorganic layer disposed on the outermost surface of the gas barrier film with the light-diffusing layer forming material. In this manner, the gas barrier film can be conveyed only by holding the end portion thereof in a non-contact manner. The conveyance in a non-contact manner can be referred to the description of JP2009-179853A.

The coating can be performed according to a known thin film forming method such as a dip coating method, an air knife coating method, a curtain coating method, a roller coating method, a wire bar coating method, a gravure coating method, a micro-gravure coating method, or an extrusion coating method. Among these, it is preferable that the coating is performed by conveying the gas barrier film in a non-contact manner, in which a roll is not in contact with an inorganic underlayer, or according to an extrusion coating method using a die coater or a slit coater. The reason for this is that only a liquid reservoir is brought into contact with the inorganic layer and a coating device is not in direct contact with the inorganic layer when the inorganic layer is coated with the light-diffusing layer forming material, in the extrusion coating method, and thus damage such as a crack or a split of the inorganic layer caused by physical contact is unlikely to occur.

Next, the light-diffusing layer forming material coated film may be dried. The drying may be performed on a laminate formed of the gas barrier film and the light-diffusing layer forming material coated film. The laminate may be conveyed to a drying unit and subjected to a drying process. As a preferred aspect, an aspect in which the drying unit is formed of a drying unit that performs heating from the surface side (coated film side) for drying and a drying unit that performs heating from the rear surface side (gas barrier film side) for drying and the applied polymerizable composition is dried from both of the surface side and the rear surface side may be exemplified. For example, the drying unit on the surface side is a hot air drying unit and the drying unit on the rear surface side may be a heat roller (pass roll having a heating mechanism).

The drying unit may perform drying on the light-diffusing layer forming material coated film by heating the whole laminate or the light-diffusing layer fanning material coated film may be dried by sufficiently heated from the gas barrier film side. Drying means is not particularly limited and any drying means may be used as long as the drying means dries the light-diffusing layer forming material (removing an organic solvent) before a film-forming material reaches a light irradiation unit according to the conveying speed or the like of the support so that a polymerizable compound can be polymerized. Specific examples of the drying means include a heat roller, a warm air heater, and a heat exchanger plate.

When these drying means are used, a hydrolysis reaction of a silane coupling agent or the like proceeds, the light-diffusing layer forming material (binder) is efficiently cured, and film formation can be carried out without damaging the gas barrier film or the like. These drying means may be used alone or in combination of plural kinds thereof. Any known drying means can be used.

The light-diffusing layer forming material may be cured by light (for example, ultraviolet rays), electron beams, or heat rays, and it is preferable that the light-diffusing layer forming material is cured by light. Particularly, it is preferable that the light-diffusing layer forming material is cured while being heated at a temperature of 25° or higher (for example, in a temperature range of 30° C. to 130° C.). When heated, the light-diffusing layer forming material is efficiently cured by promoting free movement of a polyfunctional acrylic monomer, and film formation can be carried out without damaging the gas barrier film.

Any light source for light irradiation may be used if the wavelength thereof is around the wavelength (absorption wavelength) reacting with a photopolymerization initiator. In a case where the absorption wavelength is in a ultraviolet region, examples of the light source include respective mercury lamps of an ultra-high pressure, a high pressure, a medium pressure, and a low pressure, a chemical lamp, a carbon arc lamp, a metal halide lamp, a xenon lamp, and sunlight. Various kinds of available laser light sources at a wavelength of 350 nm to 420 nm may be made into multi-beams for irradiation. Moreover, in a case where the absorption wavelength is in an infrared region, examples of the light source include a halogen lamp, a xenon lamp, and a high pressure sodium lamp, and various kinds of available laser light sources at a wavelength of 750 nm to 1400 nm may be made into multi-beams for irradiation.

In a case of photo-radical polymerization by irradiation with light, the polymerization can be carried out in air or inert gas, but it is preferable that the polymerization is carried out in an atmosphere in which the oxygen concentration is decreased as much as possible for the purpose of shortening the induction period of polymerization of a radical polymerizable monomer or sufficiently raising the polymerization rate. The oxygen concentration is preferably in a range of 0 ppm to 1000 ppm, more preferably in a range of 0 ppm to 800 ppm, and still more preferably in a range of 0 ppm to 600 ppm. The irradiation intensity of ultraviolet rays to be applied is preferably in a range of 0.1 mW/cm² to 100 mW/cm². The amount of light irradiation on the surface of a coated film is preferably in a range of 100 mJ/cm² to 10000 mJ/cm² and more preferably in a range of 100 mJ/cm² to 5000 mJ/cm², and particularly preferably in a range of 100 mJ/cm² to 1000 mJ/cm².

When the light irradiation amount is less than 100 mJ/cm², since the light-diffusing layer is not cured, the light-diffusing layer is occasionally dissolved when coated with the planarizing layer or collapsed at the time of substrate cleaning. Meanwhile, when the light irradiation amount exceeds 10000 mJ/cm², the polymerization of the light-diffusing layer proceeds too far so that the surface thereof is yellowed, the transmittance is decreased, and the light extraction efficiency is decreased in some cases.

In order to perform heating from the gas barrier film side during the roll-to-roll process, it is preferable that a film in manufacture is wound around a backup roll such that the backup roll side becomes the gas barrier film. Further, it is preferable that light irradiation is carried out while performing heating from the gas barrier film side at 30° C. or higher and lower than 100° C.

<Light-Diffusing Layer>

The content of the light-diffusing particles in the light-diffusing layer is preferably in a range of 30% by volume to 66% by volume, more preferably in a range of 40% by volume to 60% by volume, and particularly preferably in a range of 45% by volume to 55% by volume. When the content thereof is less than 30% by volume, the light extraction efficiency is occasionally decreased unless the thickness of the light-diffusing layer is sufficiently increased, since a probability of light, incident on the light-diffusing layer, being diffused in the light-diffusing particles is small and the ability of converting the angle of light of the light-diffusing layer is less. Further, an increase in thickness of the light-diffusing layer leads to an increase in cost and unevenness in thickness of the light-diffusing layer becomes large, and thus there is a concern that unevenness in scattering effects in the light emitting surface may be generated. Meanwhile, when the content thereof exceeds 66% by volume, the physical strength of the light-diffusing layer is degraded, since the surface of the light-diffusing layer is greatly roughened and cavities are generated in the inside of the light-diffusing layer.

The average thickness of the light-diffusing layer is preferably in a range of 0.5 μm to 15 μm, more preferably in a range of 1 μm to 7 μm, and particularly preferably in a range of 1.5 μm to 5 μm. The average thickness of the light of the light-diffusing layer can be acquired by cutting out a part of the light-diffusing layer and performing measurement using a scanning electron microscope (S-3400N, manufactured by Hitachi High-Technologies Corp.).

Further, the sum of the thickness of the light-diffusing layer and the thickness of the planarizing layer is in a range of 1 μm to 30 μm.

The refractive index of the binder in the light-diffusing layer is preferably in a range of 1.7 to 2.2, more preferably in a range of 1.7 to 2.1, and still more preferably in a range of 1.7 to 2.0. When the refractive index of the binder is less than 1.7, the light extraction efficiency is degraded. When the refractive index thereof exceeds 2.2, since the amount of titanium oxide fine particles, subjected to a photocatalyst inactive treatment, in the binder of the light-diffusing layer is increased, scattering becomes extremely strong and the light extraction efficiency is degraded in some cases.

In addition, it is preferable that the refractive index of the binder in the light-diffusing layer is the same as or higher than the refractive index of the light emitting layer or the electrode in the organic electroluminescent layer.

Further, the refractive index of the light-diffusing layer may be specifically in a range of 1.5 to 2.5 and preferably in a range of 1.6 to 2.2. Moreover, a difference (Δn) in refractive index between the light-diffusing layer and the planarizing layer is preferably 0.05 or less and more preferably 0.02 or less.

It is preferable that light-diffusing particles are uniformly dispersed in the surface of the light-diffusing layer and a difference in height is in a range of 0.3 μm to 2 μm.

<Planarizing Layer>

The planarizing layer is a layer for planarizing the uneven shape on the surface of the light-diffusing layer. The uneven shape on the surface of the light-diffusing layer is easily caused by the light-diffusing particles being dispersed in the surface thereof. The surface roughness (Ra) of the surface of the planarizing layer formed on the surface of the light-diffusing layer is preferably 3 nm or less in 10 μm² (a square with a side length of 10 μm). Moreover, in the present specification, the surface roughness is set to a value measured in a size of 10 μm² using an intermolecular force microscope.

It is preferable that the planarizing layer is formed from a material having a composition (composition of the binder) without light-diffusing particles in the light-diffusing layer forming material. Further, the planarizing layer can be formed in the same manner as that of the light-diffusing layer. In addition, the planarizing layer may or may not contain a silane coupling agent in the light-diffusing layer forming material, and it is preferable that the planarizing layer does not contain a silane coupling agent. The planarizing layer forming material may be a composition of the binder described above related to the light-diffusing layer forming material or the composition from which a silane coupling agent is excluded, and a polyfunctional acrylic monomer, a polymerization initiator, a surfactant, and other additives which are forming materials of the light-diffusing layer and the planarizing layer in one light-extracting layer may be in common or different from each other.

The surface of the light-diffusing layer may be coated with the planarizing layer forming material. At the time of coating, it is preferable that the planarizing layer forming material is applied in a state in which the solid concentration is 50% or less, the material contains a solvent, and the coating amount thereof is 3 mL/m² or greater. When the planarizing layer is formed in a state of the planarizing layer forming material containing a solvent, a part of the light-diffusing layer which becomes an underlayer is dissolved and anchored, and thus firm adhesion can be ensured. Moreover, it is preferable that a desired dry film is obtained after the layer is dried. It is preferable that the drying is performed such that the time for a decreasing rate of drying is 1 second or longer.

The average thickness of the planarizing layer is not particularly limited and can be suitably selected according to the purpose thereof, but is preferably in a range of 0.5 μm to 5 μm, more preferably in a range of 1 μm to 3 μm, and particularly preferably in a range of 1.5 μm to 2.5 μm.

The total average thickness of the light-diffusing layer and the planarizing layer is preferably in a range of 2 μm to 15 μm, more preferably in a range of 3 μm to 14 μm, and particularly preferably in a range of 5 μm to 12 μm.

The refractive index of the planarizing layer is preferably in a range of 1.7 to 2.2, more preferably in a range of 1.7 to 2.1, and still more preferably in a range of 1.7 to 2.0.

It is preferable that the refractive index of the planarizing layer is the same as or higher than the refractive index of the light-diffusing layer. A difference (Δn) in refractive index between the light-diffusing layer and the planarizing layer is preferably 0.05 or less and more preferably 0.02 or less.

It is preferable that a mixed layer having a thickness of 5 nm or greater is formed between the light-diffusing layer and the planarizing layer.

The presence of the mixed layer can be confirmed by cross-section TEM. Further, the film thickness of the mixed layer can be adjusted by adjusting the drying rate at the time of forming the planarizing layer and the solid content concentration of the light-diffusing layer forming material. The film thickness of the mixed layer can be increased by increasing the solvent amount and lengthening the drying time and the film thickness of the mixed layer can be decreased by increasing the solid content concentration of the planarizing layer forming material.

<Gas Barrier Film>

In the functional laminated film, the gas barrier film functions as a layer having barrier properties and as a substrate of a light-extracting layer.

The gas barrier film has a base film and a barrier laminate formed on the base film. In the gas barrier film, the barrier laminate may be provided only on one surface of the base film or provided on both surfaces thereof.

The gas barrier film may include constituent components (for example, a functional layer such as an easily adhesive layer or an easily slidable layer) other than the barrier laminate and the base film. The functional layer may be disposed on the barrier laminate, between the barrier laminate and the substrate, or a side (rear surface) on which the barrier laminate on the substrate is not disposed.

The film thickness of the gas barrier film is preferably in a range of 20 μm to 200 μm and more preferably in a range of 50 μm to 150 μm.

(Base Film)

A plastic film is typically used for the gas barrier film as a base film. The material or the thickness of the plastic film to be used is not particularly limited as long as the film is capable of holding the barrier laminate, and the plastic film can be suitably selected according to the purpose of use. Specific examples of the plastic film include a polyester resin, a methacrylic resin, a methacrylic acid-maleic acid copolymer, a polystyrene resin, a transparent fluororesin, polyimide, a fluorinated polyimide resin, a polyamide resin, a polyamide imide resin, a polyether imide resin, a cellulose acylate resin, a polyurethane resin, a polyether ether ketone resin, a polycarbonate resin, an alicyclic polyolefin resin, a polyacrylate resin, a polyether sulfone resin, a polysulfone resin, a cycloolefin copolymer, a fluorene ring-modified polycarbonate resin, an alicyclic-modified polycarbonate resin, a fluorene ring-modified polyester resin, and a thermoplastic resin such as an acryloyl compound.

The film thickness of the base film is preferably in a range of 10 μm to 250 μm and more preferably in a range of 20 μm to 130 μm.

(Barrier Laminate)

The barrier laminate includes at least one organic layer and at least one inorganic layer and may be a laminate formed of two or more organic layers and two or more inorganic layers being alternately laminated. The barrier laminate is configured such that at least one inorganic layer does not have an organic layer on the outside thereof.

The number of layers constituting the barrier laminate is not particularly limited. However, typically, the number of layers is preferably in a range of 2 to 30 and more preferably in a range of 3 to 20. In addition, the barrier laminate may include other constituent layers other than the organic layers and the inorganic layers.

The film thickness of the barrier laminate is preferably in a range of 0.5 μm to 10 μm and more preferably in a range of 1 μm to 5 μm. Moreover, the sum of the film thickness of the barrier laminate and the film thickness of the light-extracting layer is preferably in a range of 1.5 μm to 30 μm and more preferably in a range of 2 μm to 25 μm.

The barrier laminate may include a so-called gradient material layer in which an organic region and an inorganic region of the compositions constituting the barrier laminate are continuously changed in the film thickness direction within the range not departing from the gist of the present invention. Particularly, the gradient material layer may be included between a specific organic layer and an inorganic layer framed directly on the surface of the organic layer. Examples of the gradient material layer include materials described in the paper of “Journal of Vacuum Science and Technology A Vol. 23 pp. 971 to 977 (2005, American Vacuum Society) written by Kim et al. and a layer in which an organic region and an inorganic region do not have an interface therebetween and are continuous to each other as disclosed in the specification of US2004-46497A. Hereinafter, for simplification, an organic layer and an organic region are described as an “organic layer” and an inorganic layer and an inorganic region are described as an “inorganic layer.”

(Organic Layer)

Preferably, an organic layer can be formed by curing a polymerizable composition containing a polymerizable compound.

(Polymerizable Compound)

It is preferable that the polymerizable compound is a compound having an ethylenically unsaturated bond in the terminal or the side chain thereof and/or a compound having epoxy or oxetane in the terminal or the side chain thereof. It is particularly preferable that the polymerizable compound is a compound having an ethylenically unsaturated bond in the terminal or the side chain thereof. Examples of the compound having an ethylenically unsaturated bond in the terminal or the side chain thereof include a (meth)acrylate compound, an acrylamide compound, a styrene compound, and a maleic anhydride. Among these, a (meth)acrylate compound is preferable and an acrylate compound is particularly preferable.

Preferred examples of the (meth)acrylate compound include (meth)acrylate, urethane (meth)acrylate, polyester (meth)acrylate, and epoxy (meth)acrylate.

Preferred examples of the styrene compound include styrene, α-methylstyrene, 4-methylstyrene, divinylbenzene, 4-hydroxystyrene, and 4-carboxystyrene.

Specifically, as the (meth)acrylate compound, compounds described in paragraphs to [0036] of JP2013-43382A and paragraphs [0036] to [0048] of JP2013-43384 can be used. In addition, the above-described polyfunctional acrylic monomer having a fluorene skeleton can be used.

(Polymerization Initiator)

The polymerizable compound used to form an organic layer may include a polymerization initiator. In a case where a polymerization initiator is used, the content thereof is preferably 0.1% by mole or greater and more preferably in a range of 0.5% by mole to 5% by mole of the total amount of the compound related to the polymerization. With such a composition, it is possible to suitably control the polymerization reaction via an active component generating reaction. Examples of the photopolymerization initiator include commercially available IRGACURE series (such as IRGACURE 651, IRGACURE 754, IRGACURE 184, IRGACURE 2959, IRGACURE 907, IRGACURE 369, IRGACURE 379, and IRGACURE 819) (manufactured by Ciba Specialty Chemicals Inc.), DAROCURE series (such as DAROCURE TPO and DAROCURE 1173), QUANTACURE PDO, and commercially available EZACURE series (such as EZACURE TZM, EZACURE TZT, and EZACURE KTO46) (manufactured by LAMBERTI S.p.A.).

(Silane Coupling Agent)

The polymerizable composition used to form an organic layer may include a silane coupling agent. Preferred examples of the silane coupling agent include a compound having a hydrolyzable reactive group such as a methoxy group, an ethoxy group, or an acetoxy group bonded to a silicon atom; and a substituent having one or more reactive groups selected from an epoxy group, a vinyl group, an amino group, a halogen group, a mercapto group, and a (meth)acryloyl group, as a substituent bonded to the same silicon atom. It is particularly preferable that the silane coupling agent includes a (meth)acryloyl group. Specific examples of the silane coupling agent include a silane coupling agent represented by formula (1) described in WO2013/146069A and a silane coupling agent represented by Formula (1) described in WO2013/027786A.

The proportion of the silane coupling agent in the solid content (residues after volatile matters are volatilized) of the polymerizable composition is preferably in a range of 0.1% by mass to 30% by mass and more preferably in a range of 1% by mass to 20% by mass.

(Method of Preparing Organic Layer)

For preparation of an organic layer, the polymerizable composition is firstly layered. In order for the polymerizable composition to be layered, a support such as a base film or an inorganic layer may be coated with a polymerizable composition. Examples of the coating method include a dip coating method, an air knife coating method, a curtain coating method, a roller coating method, a wire bar coating method, a gravure coating method, a slide coating method, and an extrusion coating method (also referred to as a die coating method) of using a hopper described in U.S. Pat. No. 2,681,294A. Among these, an extrusion coating method is preferably employed.

When the surface of an inorganic layer is coated with a polymerizable composition used to form an organic layer, it is preferable that the coating is performed according to an extrusion coating method.

Next, the polymerizable composition applied to the surface thereof may be dried. The drying method is not particularly limited, but the above-described method of drying the light-diffusing layer forming material coated film may be used as the drying method.

The polymerizable composition may be cured by light (for example, ultraviolet rays), electron beams, or heat rays, and it is preferable that the polymerizable composition is cured by light. Particularly, it is preferable that the polymerizable composition is cured while being heated at a temperature of 25° or higher (for example, in a temperature range of 30° C. to 130° C.). When heated, the polymerizable composition is efficiently cured by promoting free movement of the polymerizable composition, and film formation can be carried out without damaging the base film or the like.

Light to be applied may be ultraviolet rays using a high pressure mercury lamp or a low pressure mercury lamp. The irradiation energy is preferably 0.1 J/cm² or greater and more preferably 0.5 J/cm² or greater. Since polymerization of the polymerizable compound is inhibited by oxygen in air, it is preferable to lower the oxygen concentration or the oxygen partial pressure during the polymerization. In a case where the oxygen concentration at the time of polymerization is lowered according to a nitrogen substitution method, the oxygen concentration is preferably 2% or less and more preferably 0.5% or less. In a case where the oxygen partial pressure at the time of polymerization is lowered according to a pressure reduction method, the total pressure is preferably 1000 Pa or less and more preferably 100 Pa or less. In addition, it is particularly preferable that light is applied with an energy of 0.5 J/cm² or greater under reduced pressure of 100 Pa or less so that ultraviolet polymerization is performed.

The polymerization rate of the polymerizable compound in the polymerizable composition after curing is preferably 20% by mass or greater, more preferably 30% by mass or greater, and particularly preferably 50% by mass or greater. The term “polymerization rate” here indicates a ratio of reacted polymerizable groups to all polymerizable groups (for example, an acryloyl group and a methacryloyl group) in a monomer mixture. The polymerization rate can be quantified according to an infrared absorption method.

It is preferable that the organic layer is smooth and has a high film hardness. The smoothness of the organic layer is preferably less than 3 nm and more preferably less than 1 nm as an average roughness (Ra value) in a size of 1 μm².

It is necessary that the surface of the organic layer do not have foreign matters, such as particles, and projections. For this reason, it is preferable that formation of the organic layer is carried out in a clean room. The degree of cleanness is preferably class 10000 or less and more preferably class 1000 or less.

It is preferable that the hardness of the organic layer is high. It is understood that the inorganic layer is formed to be smooth and thus the barrier properties thereof is improved when the hardness of the organic layer is high. The hardness of the organic layer can be expressed as a microhardness based on a nano-indentation method. The hardness of the organic layer is preferably 100 N/mm or greater and more preferably 150 N/mm or greater.

The film thickness of the organic layer is not particularly limited, but is preferably in a range of 50 nm to 5000 nm and more preferably in a range of 200 nm to 3500 nm, from the viewpoint of brittleness or light transmittance.

(Inorganic Layer)

An inorganic layer is typically a thin layer formed of a metal compound. Any method can be used as the method of forming an inorganic layer as long as a target thin film can be formed according to the method. Examples of the method include a physical vapor deposition (PVD) method such as an evaporation method, a sputtering method, or an ion plating method, various chemical vapor deposition (CVD) methods, and a liquid phase growth method such as plating or a sol-gel method. Components included in the inorganic layer are not particularly limited as long as the components have the above-described performance. For example, a metal oxide, a metal nitride, a metal carbide, a metal oxynitride, and a metal oxycarbide, specifically, an oxide, a nitride, a carbide, an oxynitride, and an oxycarbide including one or more metals selected from Si, Al, In, Sn, Zn, Ti, Cu, Ce, and Ta can be preferably used. Among these, an oxide, a nitride, or an oxynitride having metals selected from Si, Al, In, Sn, Zn, and Ti is preferable and an oxide, a nitride, or an oxynitride having a metal of Si or Al is particularly preferable. These may include other elements as secondary components. For example, the surface of the inorganic layer may be formed of silicon hydroxide.

An inorganic layer containing Si is particularly preferable as the inorganic layer from the viewpoints that the inorganic layer containing Si is more transparent and has more excellent gas barrier properties. Among these, particularly, an inorganic layer including at least one of silicon nitride, silicon oxide, or silicon oxynitride is preferable and an inorganic layer formed of silicon nitride is more preferable.

The inorganic layer may suitably contain hydrogen by, for example, an oxide, a nitride, and an oxynitride of metals containing hydrogen, but it is preferable that the hydrogen concentration in front Rutherford scattering is 30% or less.

The smoothness of the inorganic layer formed in the present invention is preferably less than 3 nm and more preferably 1 nm or less as an average roughness (Ra value) in a size of 1 μm².

The thickness of the inorganic layer is not particularly limited, but one inorganic layer is typically in a range of 5 nm to 500 nm, preferably in a range of 10 nm to 200 nm, and still more preferably in a range of 15 nm to 50 nm. The inorganic layer may have a laminated structure formed of a plurality of sub-layers. In this case, respective sub-layers may have compositions which are the same as or different from each other.

(Lamination of Organic Layer and Inorganic Layer)

Organic layers and inorganic layers can be laminated on each other by sequentially and repeatedly forming organic layers and inorganic layers according to a desired layer configuration.

(Functional Layer)

The barrier laminate of the present invention may include a functional layer. Functional layers are described in detail in paragraphs [0036] to [0038] of JP2006-289627A. Examples of functional layers other than those described in JP2006-289627A include a matting agent layer, a protective layer, a solvent resistance layer, an antistatic layer, a smoothing layer, an adhesion improving layer, a light-shielding layer, an antireflection layer, a hard coat layer, a stress relaxation layer, an antifogging layer, an antifouling layer, and a layer to be printed.

As described above, an easily adhesive layer or an easily slidable layer may be provided to be disposed between a base film and an organic layer (organic layer on a side closest to the base film in the barrier laminate) in the gas barrier film.

Examples of the easily adhesive layer include layers formed from materials such as urethane, urethane acrylate, and acrylate. Further, examples of the easily slidable layer include layers formed by adding a filler or particles to the materials used to form the above-described easily adhesive layer.

<Applications of Functional Laminated Film>

A functional laminated film can be used for applications which require a layer to have barrier properties, a light-diffusing function, and the like. It is particularly preferable that the functional laminated film is used as a film substrate for an organic electroluminescent device.

(Film Substrate for Organic Electroluminescent Device)

The organic electroluminescent device including the functional laminated film of the present invention has a configuration in which a transparent electrode and a reflective electrode are disposed on the functional laminated film and an organic electroluminescent layer is disposed between the transparent electrode and the reflective electrode. It is preferable that the organic electroluminescent device includes the functional laminated film, the transparent electrode, the organic electroluminescent layer, and the reflective electrode in this order. It is preferable that the organic electroluminescent device is a bottom emission type device. The organic electroluminescent layer indicates a layer which has at least a light emitting layer and may include respective layers such as a hole transport layer, an electron transport layer, a hole blocking layer, an electron blocking layer, a hold injection layer, and an electron injection layer, as functional layers other than the light emitting layer.

The organic electroluminescent device may further include a configuration such as a sealing can for sealing the transparent electrode, the reflective electrode, and the organic electroluminescent layer. With the gas barrier film and an additional sealing structure in the functional laminated film, the transparent electrode, the reflective electrode, the organic electroluminescent layer, the planarizing layer, and the light-diffusing layer may be sealed. In a case where the transparent electrode is provided on the surface of the light-extracting layer, a difference (Δn) in refractive index between the transparent electrode and the light-extracting layer may be decreased. The difference (Δn) in refractive index therebetween is preferably 0.2 or less and more preferably 0.15 or less. In addition, a typical ITO serving as a transparent electrode has a refractive index n of approximately 1.8 to 2.

An organic electroluminescent layer, each layer in the organic electroluminescent layer, preparation materials or configurations of a transparent electrode and a reflection electrode, lamination order, and the configuration of an organic electroluminescent device can be referred to the description in paragraphs [0081] to [0122] of JP2012-155177A.

### EXAMPLES

The present invention will be described in detail with reference to the following examples. The materials, the use amounts, the proportions, the treatment contents, and the treatment procedures described in the following examples can be appropriately changed within the range not departing from the gist of the present invention. Accordingly, the scope of the present invention is not limited to the following examples.

### Example 1

(Method of Preparing Gas Barrier Film)

(Formation of First Layer)

An organic layer coating composition including 100 parts by mass of a polymerizable compound (trimethylolpropane triacrylate (TMPTA, manufactured by Daicel Cytec Corp.), a photopolymerization initiator (IRGACURE 819, manufactured by Ciba Specialty Chemicals Inc.), and methyl ethyl ketone (MEK) was prepared. The amount of MEK was set such that “{(mass of polymerizable compound+mass of photopolymerization initiator)/total mass of coating solution}×100%” was 15%.

A polyethylene naphthalate (PEN) film (TEONEX Q65FA, manufactured by Teijin DuPont Films Japan Ltd., thickness of 100 μm, width of 1000 mm) serving as a base film was coated with the organic layer coating composition obtained in the above-described manner using a die coater according to a roll-to-roll system such that the coating amount thereof was set to 9 mL/m², and the coated film was allowed to pass through a drying zone at 50° C. for 3 minutes. Thereafter, the coated film was irradiated (integrated amount of irradiation of approximately 600 mJ/cm²) with ultraviolet rays, cured, and then wound. The thickness of a first organic layer formed on the base film was 1 μm.

(Formation of Second Layer)

Next, an inorganic layer (silicon nitride layer) was formed, as a second layer, on the surface of the above-described first organic layer using a CVD device of a roll-to-roll system. As raw material gas, silane gas (flow rate of 160 sccm at 0° C., standard state at 1 atm, the same applies to hereinafter), ammonia gas (flow rate of 370 sccm), hydrogen gas (flow rate of 590 sccm), and nitrogen gas (flow rate of 240 sccm) were used. A high frequency power source having a frequency of 13.56 MHz was used as a power source. The film formation pressure was 40 Pa and the ultimate film thickness was 50 nm. In this manner, an inorganic layer was laminated on the surface of the first organic layer. The obtained laminated film was wound.

(Formation of Third Layer)

An organic layer coating composition including 100 parts by mass of a polymerizable compound (trimethylolpropane triacrylate (TMPTA, manufactured by Daicel Cytec Corp.), a photopolymerization initiator (IRGACURE 819, manufactured by Ciba Specialty Chemicals Inc.), 3 parts by mass of a silane coupling agent (KBM 5103, manufactured by Shin-Etsu Chemical Co., Ltd.) and methyl ethyl ketone (MEK) was prepared. The amount of MEK was set such that the ratio of the solid content to the coating solution was 15% when the weight ratio of “(polymerizable compound+photopolymerization initiator)/total weight of coating solution” was used as the ratio of the solid content to the coating solution.

The surface of the inorganic layer was coated with this organic layer coating composition using a die coater according to a roll-to-roll system such that the coating amount thereof became 9 mL/m², and the coated film was allowed to pass through a drying zone at 100° C. for 3 minutes. Thereafter, while the coated film was rolled around a heat roll heated at 60° C., the coated film was irradiated (integrated amount of irradiation of approximately 600 mJ/cm²) with ultraviolet rays, cured, and then wound. The thickness of a second organic layer formed on the base film was 1 μm. The obtained laminated film was wound.

(Formation of Fourth Layer)

Next, an inorganic layer (silicon nitride layer) was formed on the surface of the second organic layer using a CVD device of a roll-to-roll system. As raw material gas, silane gas (flow rate of 160 sccm), ammonia gas (flow rate of 370 sccm), hydrogen gas (flow rate of 590 sccm), and nitrogen gas (flow rate of 240 sccm) were used. A high frequency power source having a frequency of 13.56 MHz was used as a power source. The film formation pressure was 40 Pa and the ultimate film thickness was 50 nm. In this manner, an inorganic layer was laminated on the surface of the second organic layer. Subsequently, a protective PE film was adhered thereto and wound, thereby preparing a gas barrier film having a length of 100 m.

(Formation of Light-Extracting Layer)

(Formation of Light-Diffusing Layer)

As binder resin materials, 500 g of a difunctional acrylate monomer (EB150: 1,6-hexanediol diacrylate, manufactured by Daicel Cytec Corp.) and 150 g of a silane coupling agent (KBM 5103, manufactured by Shin-Etsu Chemical Co., Ltd.) were added to 2050 g of a titanium oxide fine particle dispersion liquid (HTD 1061, manufactured by TAYCA Corp.), and the solution was diluted with 1500 g of methyl isobutyl ketone (MIBK, manufactured by Wako Pure Chemical Industries, Ltd.), thereby preparing a binder. While the obtained binder was stirred, 790 g of light-diffusing particles (MX-150, cross-linked acrylic particles having an average particle size of 1.5 μm, refractive index of 1.49, manufactured by Soken Chemical & Engineering Co., Ltd.) were added thereto, and then the mixer was stirred for 1 hour. 10 g of a polymerization initiator (IRGACURE 819, manufactured by Ciba Specialty Chemicals Inc.) was added to the obtained binder having the light-diffusing particles, thereby preparing 5000 g of a light-diffusing layer forming material.

While the protective PE film of the gas barrier film was peeled off, the surface of the fourth layer of the gas barrier film was coated with the light-diffusing layer forming material using a die coater. The liquid sending amount was adjusted so that the coating amount thereof was set to 18 mL/m². The thickness of the coated film after drying was 4 μm. After the protective PE film of the gas barrier film was peeled off, the gas barrier film was conveyed to the die coater such that the surface of the fourth layer was not brought into contact with a pass roll. Specifically, the gas barrier film was conveyed only by holding the end portion thereof using a non-contact stepped roll as a film surface touch roll. After the coated film coated with the material using a die coater was allowed to stand still at room temperature for 10 seconds, dry air at 60° C. was applied to the coated film for 2 minutes and then dry air at 110° C. was further applied to the coated film for 2 minutes so that the film was dried until the temperature of the base became 110° C. Next, heat was transferred while a backup roll held such that the base film surface side of the gas barrier film became the roll side was heated at 80° C., and the roll was irradiated with ultraviolet rays at the same time using an ultraviolet irradiation device which was set such that the integrated amount of irradiation was adjusted to approximately 600 mJ. In this manner, a light-diffusing layer was formed by curing a coated film. The obtained laminated film was wound according to the winding diameter while the winding tension was controlled to be constant, thereby preparing a film roll on which the light-diffusing layer was formed.

(Formation of Planarizing Layer)

860 g of a fluorene derivative (OGSOL EA-0200 ((9,9-bis(4-(2-acryloyloxyethyloxy)phenyl)fluorene), manufactured by Osaka Gas Chemicals Co., Ltd.) was added to 3000 g of a titanium oxide fine particle dispersion liquid (HTD 1061, manufactured by TAYCA Corp.), and the solution was diluted with 1130 g of propylene glycol monomethyl ether (PGME, manufactured by Wako Pure Chemical Industries, Ltd.). 10 g of a polymerization initiator (IRGACURE 819, manufactured by Ciba Specialty Chemicals Inc.) was added to the obtained solution, thereby preparing 5000 g of a planarizing layer forming material.

The film roll was set to feeding of a coating machine and conveyed to a die coater portion at a conveying speed of 10 m/min, and the light-diffusing layer surface of the film roll was coated with the prepared planarizing layer forming material. The liquid sending amount was adjusted so that the coating amount thereof was set to 9 mL/m². After the coated film was allowed to stand still at room temperature for 10 seconds, dry air at 60° C. was applied to the coated film for 2 minutes and then dry air at 110° C. was further applied to the coated film for 2 minutes so that the film was dried until the temperature of the substrate became 110° C. The thickness of the coated film after drying was 2 μm. Next, heat was transferred while a backup roll held such that the base film surface side of the gas barrier film became the roll side was heated at 80° C., and the roll was irradiated with ultraviolet rays at the same time using an ultraviolet irradiation device which was set such that the integrated amount of irradiation was adjusted to approximately 600 mJ. In this manner, a planarizing layer was formed by curing a coated film. The obtained laminated film was wound according to the winding diameter while the winding tension was controlled to be constant, thereby preparing a film roll serving as a functional laminated film.

(Evaluation of Adhesion)

The light-extracting layer formed on the gas barrier film was marked with a cutter using a cross-cut 100 square method, adhesive tape NITTOTAPE (No 31-B, manufactured by Nitto Denko Corp.) was adhered thereto and then peeled off, and the adhesion was evaluated based on the number of remaining squares. The evaluation criteria are as follows.

The number of squares was in a range of 90 to 100: AA

The number of squares was 80 or greater and less than 90: A

The number of squares was 70 or greater and less than 80: B

The number of squares was 60 or greater and less than 70: C

The number of squares was 60 or less: D

(Evaluation of Light Extraction Efficiency)

An organic electroluminescent device including a functional laminated film and an organic electroluminescent element was prepared, and the light extraction efficiency was evaluated. The organic electroluminescent device was prepared by forming an organic electroluminescent element on a functional laminated film as follows.

An indium tin oxide (ITO) was formed on a planarizing layer of the functional laminated film according to a sputtering method such that the thickness thereof became 100 nm. Next, a hole injection layer was co-deposited on the ITO such that the thickness thereof became 250 nm. The hole injection layer was obtained by doping F4-TCNQ represented by the following structural formula, in an amount of 0.3% by mass, to 4,4′,4″-tris(N,N-(2-naphthyl)-phenylamino)triphenylamino(2-TNATA) represented by the following structural formula. Subsequently, α-NPD(Bis[N-(1-naphthyl)-N-phenyl]benzidine) was formed on the hole injection layer as a first hole transport layer according to a vacuum deposition method such that the thickness thereof became 7 nm. Next, an organic material A represented by the following structural formula was vacuum-deposited on the first hole transport film, thereby forming a second hole transport layer having a thickness of 3 nm.

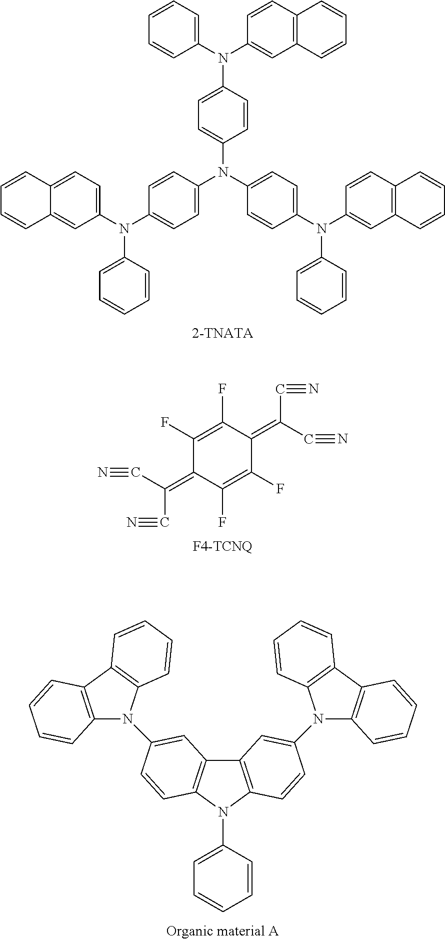 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; N#CC(C#N)=c1c(F)c(F)c(=C(C#N)C#N)c(F)c1F ; c1ccc(-n2c3ccc(-n4c5ccccc5c5ccccc54)cc3c3cc(-n4c5ccccc5c5ccccc54)ccc32)cc1]

Next, a light emitting layer was vacuum-deposited on the second hole transport layer such that the thickness thereof became 30 nm. The light emitting layer was obtained by doping a light emitting material A, in an amount of 40% by mass with respect to mCP (1,3-Bis(carbazol-9-yl)benzene), to the mCP serving as a host material. The light emitting material A is a phosphorescent light emitting material and represented by the following structural formula.

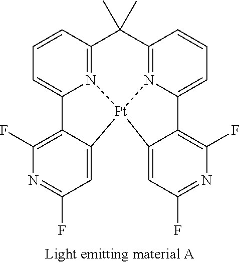

Next, BAlq (Bis-(2-methyl-8-quinolinolato)-4-(phenyl-phenolate)-aluminium (III)) represented by the following structural formula was vacuum-deposited on the light emitting layer as an electron transport layer such that the thickness thereof became 39 nm.

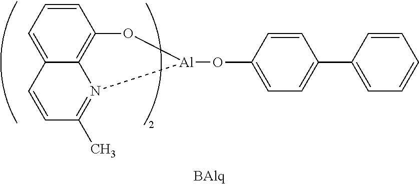

Next, BCP (2,9-dimethyl-4,7-diphenyl-1,10-phenanthroline) represented by the following structural formula was vapor-deposited on the electron transport layer as an electron injection layer such that the thickness thereof was 1 nm.

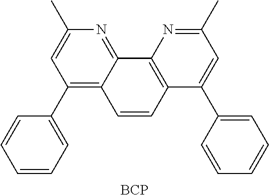

Next, LiF serving as a buffer layer was vapor-deposited on the electron injection layer such that the thickness thereof became 1 nm and then aluminum serving as an electrode layer was vapor-deposited on the buffer layer such that the thickness thereof became 100 nm, thereby preparing an organic electroluminescent element on the functional laminated film. Next, a drying agent was adhered to the laminate formed of the gas barrier film, the light-extracting layer, and the organic electroluminescent element in a nitrogen gas atmosphere, and the light-extracting layer and the organic electroluminescent element were enclosed by a sealing glass can. The outer peripheral portions of the gas barrier film and the sealing glass can were coated with a sealing material to be interposed therebetween for sealing. In this manner, an organic electroluminescent device was prepared.

The light extraction efficiency of organic electroluminescent devices prepared in the above-described manner was evaluated as follows.

The external quantum yield was measured by applying a DC constant current to each organic electroluminescent device for light emission using an external quantum efficiency measuring device “C9920-12” (manufactured by Hamamatsu Photonics K. K.). The light extraction efficiency was calculated according to the following equation.

Light extraction efficiency=(external quantum efficiency of each example and each comparative example/external quantum efficiency when organic electroluminescent element was formed on gas barrier film without light-extracting layer)×100

The evaluation was performed based on the following criteria.

The light extraction efficiency was 180% or greater: AA

The light extraction efficiency was 150% or greater and less than 180%: A

The light extraction efficiency was 130% or greater and less than 150%: B

The light extraction efficiency was 110% or greater and less than 130%: C

The light extraction efficiency was less than 110%: D

(Evaluation of Temporal Stability (Element Durability))

In shrink measurement of a light-emitting area, evaluation of the temporal change was performed on the organic electroluminescent devices. The organic electroluminescent devices of each example and each comparative example were put under the conditions of a temperature of 40° C. and a relative humidity of 90% and allowed to stand still for 1 week. The changes of the light-emitting areas before and after 1 week were compared to each other. It was understood that the temporal stability was weak when the light-emitting area changed greatly and the temporal stability was strong when the light-emitting area changed less.

Change in Light-Emitting Areas
90% or greater:. AA
80% or greater and less than 90%: A
70% or greater and less than 80%: B
60% or greater and less than 70%: C
Less than 60%: D

The results are listed in Table 1.

Further, in Examples 2 to 17 and Comparative Examples 1 to 9, functional laminated films and organic electroluminescent devices were prepared by changing the procedures of Example 1 as follows. The evaluation was performed as described above. The results are listed in Table 1.

### Example 2

The total amount of monomers of the light-diffusing layer foaming material was changed into OGSOL EA-0200 (manufactured by Osaka Gas Chemicals Co., Ltd.).

### Example 3

The total amount of the silane coupling agent of the light-diffusing layer fanning material was changed into KR 513 (manufactured by Shin-Etsu Chemical Co., Ltd.).

### Example 4

EB 150 of the light-diffusing layer forming material was reduced by an amount of 10 g and 10 g of a fluorine-based surfactant (FC4430 manufactured by 3M Co., Ltd.) was added in place of 10 g of EB150. OGSOL EA-0200 of the planarizing layer forming material was reduced by an amount of 10 g and 10 g of a fluorine-based surfactant (FC4430 manufactured by 3M Co., Ltd.) was added in place of 10 g of EB150.

### Example 5

The film thickness of the light-diffusing layer was set to 6 μm.

### Example 6

The film thickness of the light-diffusing layer was set to 10 μm.

### Example 7

The film thickness of the planarizing layer was set to 2.8 μm.

### Example 8

The film thickness of the planarizing layer was set to 4 μm.

### Example 9

A mixed layer of light-diffusing layer and a planarizing layer was formed to have a film thickness of 20 nm between the light-diffusing layer and the planarizing layer by reducing the solid content concentration in half, doubling the coating amount, and doubling the drying time at room temperature.

### Example 10

The coating amount of the planarizing layer forming material was set to 12 mL/m².

### Example 11

The coating amount of the planarizing layer forming material was set to 6 mL/m².

### Example 12

The drying temperature of the light-diffusing layer forming material coated film was set to 110° C. and the drying time thereof was set to 4 minutes.

### Example 13

The drying temperature of the light-diffusing layer forming material coated film was set to 100° C. and the drying time thereof was set to 4 minutes.

### Example 14

The heating temperature at the time of irradiation with ultraviolet rays when the light-diffusing layer was formed was set to 60° C.

### Example 15

The heating temperature at the time of irradiation with ultraviolet rays when the light-diffusing layer was formed was set to 40° C.

### Example 16

The solvent of the planarizing layer forming material was set to MIBK.

### Comparative Example 1

The silane coupling agent was removed from the light-diffusing layer forming material and TMPTA was used in place of EB 150 (manufactured by Daicel Cytec Corp.) as a monomer.

### Comparative Example 2

A fifth layer, as an organic layer, was formed on the surface of the fourth layer. A light-diffusing layer was formed on the surface of the fifth layer.

The fifth layer was formed in the same manner as that of the second layer.

TABLE 1

| | Exam- | Exam- | Exam- | Exam- | Exam- | Exam- |
|---|---|---|---|---|---|---|
| | ple 1 | ple 2 | ple 3 | ple 4 | ple 5 | ple 6 |
| Adhesion | A | AA | AA | AA | B | C |
| Light | A | A | A | A | AA | AA |
| extraction | | | | | | |
| efficiency | | | | | | |
| Element | A | A | A | A | A | A |
| durability | | | | | | |
| | Exam- | Exam- | Exam- | Exam- | Exam- | Exam- |
| | ple 7 | ple 8 | ple 9 | ple 10 | ple 11 | ple 12 |
| Adhesion | B | C | AA | AA | B | AA |
| Light | A | A | A | A | A | A |
| extraction | | | | | | |
| efficiency | | | | | | |
| Element | AA | AA | A | A | A | A |
| durability | | | | | | |
| | | | | | Com- | Com- |
| | | | | | parative | parative |
| | Exam- | Exam- | Exam- | Exam- | Exam- | Exam- |
| | ple 13 | ple 14 | ple 15 | ple 16 | ple 1 | ple 2 |
| Adhesion | B | B | C | AA | D | D |
| Light | A | A | A | AA | A | D |
| extraction | | | | | | |
| efficiency | | | | | | |
| Element | A | A | A | A | D | D |
| durability | | | | | | |

### EXPLANATION OF REFERENCES

1: light-extracting layer

2: gas barrier film

11: light-diffusing layer

12: planarizing layer

21: inorganic layer

22: organic layer

23: base film

What is claimed is:

1. A functional laminated film comprising:
a gas barrier film; and
a light-extracting layer provided on the surface of the gas barrier film,
wherein the gas barrier film includes a base film and a barrier laminate provided on the base film,
the barrier laminate includes an organic layer and an inorganic layer,
the light-extracting layer includes a light-diffusing layer and a planarizing layer,
the inorganic layer and the light-diffusing layer are in direct contact with each other,
the light-diffusing layer is a layer formed of a light-diffusing layer forming material including light-diffusing particles and a binder,
the light-diffusing particles are organic particles, and
the binder contains titanium oxide fine particles, a polyfunctional acrylic monomer, and a silane coupling agent.

2. The functional laminated film according to claim 1, wherein the silane coupling agent has a (meth)acryloyl group.

3. The functional laminated film according to claim 1, wherein the polyfunctional acrylic monomer has a fluorene skeleton.

4. The functional laminated film according to claim 2, wherein the polyfunctional acrylic monomer has a fluorene skeleton.

5. The functional laminated film according to claim 1, wherein the binder includes a fluorine-based surfactant.

6. The functional laminated film according to claim 2, wherein the binder includes a fluorine-based surfactant.

7. The functional laminated film according to claim 3, wherein the binder includes a fluorine-based surfactant.

8. The functional laminated film according to claim 1, wherein the barrier laminate includes an organic layer, an inorganic layer, an organic layer, and an inorganic layer in this order from the base film side.

9. The functional laminated film according to claim 1, wherein the inorganic layer in contact with the light-diffusing layer includes at least one of silicon nitride, silicon oxide, or silicon oxynitride.

10. The functional laminated film according to claim 1, wherein the film thickness of the light-diffusing layer is in a range of 0.5 μm to 15 μm.

11. The functional laminated film according to claim 1, wherein the film thickness of the light-extracting layer is in a range of 1 μm to 20 μm.

12. The functional laminated film according to claim 1, wherein the total film thickness of the barrier laminate and the light-extracting layer is in a range of 1.5 μm to 30 μm.

13. The functional laminated film according to claim 1,
wherein a mixed layer of the light-diffusing layer and the planarizing layer, which has a film thickness of 5 nm or greater, is interposed between the light-diffusing layer and the planarizing layer, and
a Si—O—Si bond is formed at the interface between the light-diffusing layer and the inorganic layer in contact with the light-diffusing layer.

14. A method for producing the functional laminated film according to claim 1, comprising:
(1) coating the surface of an inorganic layer which is the surface of a gas barrier film with the light-diffusing layer forming material;
(2) irradiating a laminate formed of the gas barrier film and the light-diffusing layer forming material coated film, which is obtained after the coating, with light;
(3) coating the surface of the light-diffusing layer in a laminate formed of the gas barrier film and the light-diffusing layer, which is obtained after the irradiating of the laminate with light, with a planarizing layer forming material that contains titanium oxide fine particles and a polyfunctional acrylic monomer; and
(4) irradiating a laminate formed of the gas barrier film, the light-diffusing layer, and the planarizing layer forming material coated film, which is obtained after the coating, with light,
wherein the above-described (1) to (4) are continuously performed using a roll-to-roll system that includes winding or rewinding the gas barrier film or any one of the laminates around a roll.

15. The production method according to claim 14, further comprising:
drying the light-diffusing layer forming material coated film with hot air; and
drying the planarizing layer forming material coated film with hot air.

16. The production method according to claim 14, further comprising:
conveying the gas barrier film wound around the roll only by holding the end portion thereof using a stepped roll, which is not in contact with the surface of the gas barrier film, before the coating (1),
wherein the coating (1) is performed using a die coater or a slit coater which is not in contact with the surface of the gas barrier film.

17. The production method according to claim 14, further comprising:
heating one or more laminates selected from the group consisting of the laminate formed of the gas barrier film and the light-diffusing layer forming material coated film and the laminate formed of the gas barrier film, the light-diffusing layer, and the planarizing layer forming material coated film, with hot air or using a heating roller.

18. The production method according to claim 14, wherein one or more processes of irradiation with light selected from the group consisting of the irradiating (2) of the laminate with light and the irradiating (4) of the laminate with light are performed while heating the respective laminates from the gas barrier film side at 30° C. or higher and less than 100° C.

19. An organic electroluminescent device comprising a transparent electrode, an organic electroluminescent layer, and a reflective electrode which are provided on the surface of the functional laminated film according to claim 1 on the light-extracting layer side in this order.

20. A functional laminated film comprising:
a base film;
an inorganic layer; and
a light-diffusing layer in direct contact with the inorganic layer, in this order,
wherein the light-diffusing layer contains organic particles, titanium oxide fine particles, an acrylic polymer, and a silane coupling agent.
